(19) United States
(12) Patent Application Publication
(10) Pub. No.: US 2009/0021283 A1
(43) Pub. Date: Jan. 22, 2009

(54) HIGH SPEED LATCHED COMPARATOR

(75) Inventors: Robert F. Payne, Lucas, TX (US); Marco Corsi, Parker, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/957,640

(22) Filed: Dec. 17, 2007

Related U.S. Application Data
(60) Provisional application No. 60/950,418, filed on Jul. 18, 2007.

(51) Int. Cl. H03K 5/22

(52) U.S. Cl. 327/63

(57) ABSTRACT

An improved latched comparator, including a track mode circuit, a latch and a latch and track select circuit. The track mode circuit includes two transistors having their sources connected together, and their respective gates receiving a respective first and second input, and their drains connected to the power supply by respective resistors. The latch includes a further two transistors having their sources connected together, a gate of each connected to a drain of the other, and their drains connected to a respective one of the common connection node of the first transistor and the first resistor, and the second transistor and the second resistor. The latch and track select circuit includes a further transistor having an source connected to a current sink connected to ground, having a gate connected to receive a track signal and having a drain connected to the common connection node of the first and second transistors, and a still further transistor having a source connected to the current sink connected to ground, having a gate connected to receive a latch signal and having a drain connected to the common connection node of the third and fourth transistors. Bipolar embodiments are also included.

### TECHNICAL FIELD OF THE INVENTION

The present invention relates to latched comparators, and more particularly relates to such comparators intended for use in high speed applications.

### BACKGROUND OF THE INVENTION

High speed latched comparators are widely used in modern electronic applications. For example, they are a component of high speed analog-to-digital converters, which are used extensively in products for the communications industry. The progress of technology brings ever increasing demands for faster performance of circuits, and latched comparators must meet those demands.

FIG. 2 is a circuit design of an exemplary prior art high speed latched comparator 200. In it, a pair of signals, (+) and (−) are applied to the inputs of a preamplifier 201 which supplies its output to the inputs of a track mode amplifier 202. An output amplifier 203 provides the result of the latched comparison to a pair of bipolar transistors 204 and 205 connected in emitter follower configuration, and supplied by current sinks 206 and 207, respectively. The common connection nodes of transistor 204 and current sink 206, and of transistor 205 and current sink 207, form the respective output nodes of the latched comparator 200. A pair of bipolar transistors, 208 and 209, have their emitters connected together and to a current sink 210, with their collectors connected, respectively, to the track mode amplifier 202 and the output amplifier 203, all as shown. The base of transistor 208 receives a TRACK signal TRK, while the base of transistor 209 receives a LATCH signal LAT.

In FIG. 2, during the track phase of operation, signal TRK is high and signal LAT is low, causing transistor 208 to conduct substantially all of the current sunk by current sink 210. This allows the track mode amplifier to continuously track the amplified input signals, while the output amplifier 203 is kept off. During the latch phase of operation, signal LAT is high and signal TRK is low, causing transistor 209 to conduct substantially all of the current sunk by current sink 210. During this phase, the final result of the comparison of the amplified input signals, manifested as the signal levels at the respective collectors of the transistors in the track mode amplifiers, is transferred to the respective bases of output transistors 204 and 205, the emitters of which provide the output signals and which set the output amplifier 203 to latch that result.

A problem of the latched comparator 200 of FIG. 2 is that it is speed limited. Specifically, the latch is loaded by several components. For example, in order to make the latch fast, output emitter followers are included. However, the emitter followers consume power and load the latch. On the other hand, if emitter followers are not used, then the latch has difficulty driving subsequent loads. A further problem is that any load at OUT+/OUT− in the latched comparator of FIG. 2 is contained within the latch positive feedback loop. Thus, the performance of the latch 200 has a dependency on the output loading. This prevents optimization of the latch design without knowing a priori what the load will be.

Thus, it is desirable to have a latched comparator that overcomes the limitations of the prior art, to allow further performance improvements in such circuits.

### SUMMARY OF THE INVENTION

The following summary presents a simplified description of the invention, and is intended to give a basic understanding of one or more aspects of the invention. It does not provide an extensive overview of the invention, nor, on the other hand, is it intended to identify or highlight key or essential elements of the invention, nor to define the scope of the invention. Rather, it is presented as a prelude to the Detailed Description, which is set forth below, wherein a more extensive overview of the invention is presented. The scope of the invention is defined in the Claims, which follow the Detailed Description, and this section in no way alters or affects that scope.

The present invention provides an improved latched comparator, including a track mode circuit, a latch and a latch and track select circuit. The track mode circuit includes two transistors having their emitters connected together, and their respective bases receiving a respective first and second input, and their collectors connected to the power supply by respective resistors. The latch includes a further two transistors having their emitters connected together, a base of each connected to a collector of the other, and their collectors connected to a respective one of the common connection node of the first transistor and the first resistor, and the second transistor and the second resistor. The latch and track select circuit includes a further transistor having an emitter connected to a current sink connected to ground, having a base connected to receive a track signal and having a collector connected to the common connection node of the first and second transistors, and a still further transistor having a emitter connected to the current sink connected to ground, having a base connected to receive a latch signal and having a collector connected to the common connection node of the third and fourth transistors. The invention encompasses CMOS embodiments, as well.

These and other aspects and features of the invention will be apparent to those skilled in the art from the following detailed description of the invention, taken together with the accompanying drawings.

### BRIEF DESCRIPTION OF THE DRAWINGS

FIG. 1 is a circuit diagram of a preferred embodiment of the present invention.

FIG. 2 is a circuit diagram of a prior art bipolar latched comparator.

FIG. 3 is a circuit diagram of a prior art MOS latched comparator.

FIG. 4 is a circuit diagram of an other preferred embodiment of the present invention.

### DETAILED DESCRIPTION OF THE PREFERRED EMBODIMENT

The making and use of the various embodiments are discussed below in detail. However, it should be appreciated that the present invention provides many applicable inventive concepts which can be embodied in a wide variety of specific contexts. The specific embodiments discussed are merely illustrative of specific ways to make and use the invention, and do not limit the scope of the invention.

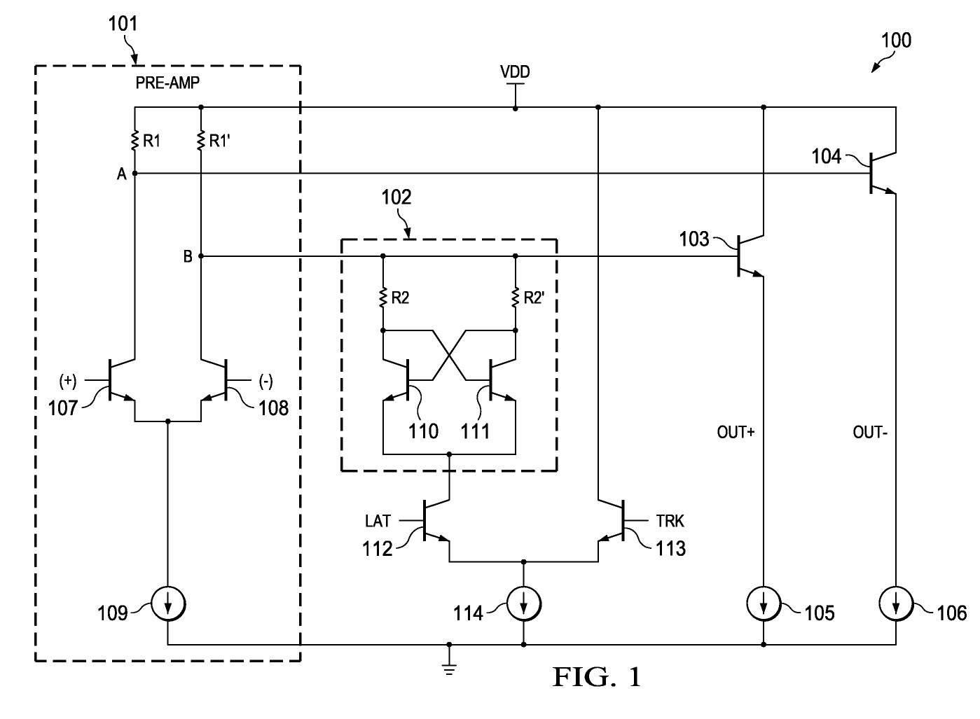

FIG. 1 is a circuit diagram showing a preferred embodiment of the present invention. The improved latched comparator 100 includes a pre-amplifier 101 and cross-coupled output latch 102, as well as a pair of NPN bipolar transistors, 103 and 104, configured in emitter-follower configuration and having their emitters connected to current sinks 105 and 106 connected to ground, respectively.

The pre-amplifier 101 includes a pair of NPN bipolar transistors 107 and 108 having their emitters connected together and to a current sink 109 connected to ground. The bases of transistors 107 and 108 are connected to the (+) and (−) inputs, respectively. The collector of transistor 107 is connected to the power supply positive terminal at voltage VDD through resistor R1, while the collector of transistor 108 is connected to the power supply at VDD through resistor R1′. The common connection node of transistor 107 and resistor R1 is node A and is connected to the base of transistor 104, while the common connection node of transistor 108 and resistor R1′ is node B and is connected to the base of transistor 103. The collectors of transistors 103 and 104 are connected to the power supply.

The output latch 102 includes a pair of NPN bipolar transistors 110 and 111 having their emitters connected together and to the collector of an NPN bipolar transistor 112. The collector of transistor 110 is connected to node B through resistor R2 and to the base of transistor 111. The collector of transistor 111 is connected to node A through resistor R2′ and to the base of transistor 110. Transistors 110 and 111 are thus connected in a classic cross-coupled latch configuration.

The emitter of transistor 112 is connected to a current sink 114 connected to ground, as is the emitter of an NPN bipolar transistor 113. The base of transistor 112 is connected to a LATCH signal LAT, while the base of transistor 113 is connected to a TRACK signal TRK. The collector of transistor 113 is connected to the power supply.

Note that in the circuit 100, the load resistances of the pre-amplifier 101 and the latch 102 are partially shared and partially split, thus providing reduced load dependency of latch performance compared to prior art approaches. Further, the cross-coupled latch 102 is isolated from the remainder of the circuit, further reducing load dependency of latch performance. Preferably, the cross-coupled latch 102 is designed to have as little parasitic capacitance as is possible, to optimize the performance of the latch. Unlike other bipolar latch circuits, the output latch 102 is not driven by a pair of emitter followers, although emitter followers can be provided, as shown, to drive a possible output load. By eliminating the emitter followers, however, higher order poles that potentially degrade the latch time constant can also be eliminated.

In operation, during the track phase, the transistor 113 shunts the current from a current source to the power supply. Note that in designing a circuit using the inventive principles, it is also possible to either shut off this current entirely or use it in some other circuit during the track phase. The pre-amplifier stage 101 drives an amplified version of the inputs across its output resistor pair (R1, R1′). Since no current is driven through the latch differential pair, the voltages at nodes A and B are likewise present at the nodes shared between the bases of the cross-coupled differential pair and the opposite sides of the resistors R2, R2′.

When the signal TRK is driven negative with respect to the signal LAT, the latching operation begins. The cross-coupled differential pair 110, 111, has current forced through it via transistor 112. Due to the positive feedback of the cross-coupled latch, the signal present at nodes A and B is regeneratively gained. At these nodes, the absolute minimum capacitance exists (collector substrate capacitance, base capacitance, and resistor capacitance of R2, R2′). Any additional capacitance from the pre-amp, load resistors R1, R1′, and the bases of any output stage is isolated from the latch transistors 110, 111, by R2, R2′. The latch time constant is therefore as fast as possible for a given process and power consumption.

As mentioned above, in typical prior art approaches, in order to make the latch fast, output emitter followers are included, which consume power and load the latch. By contrast, the preferred embodiment of the invention requires no emitter followers in the pre-amp stage, eliminating their area and power consumption. The pre-amp stage is directly coupled to the latch stage and the latched nodes are isolated from all other nodes in the circuit by the pair of resistors R2, R2′. The embodiment shown in FIG. 1 also has no emitter followers in the cross-coupled feedback path. The circuit also shunts the current from the latch to the power supply during the track phase.

Several other advantages are evident. In a typical prior art latch, there are 18 transistors and 10 resistors. This solution only requires 12 transistors and 8 resistors. This results in a significant area savings.

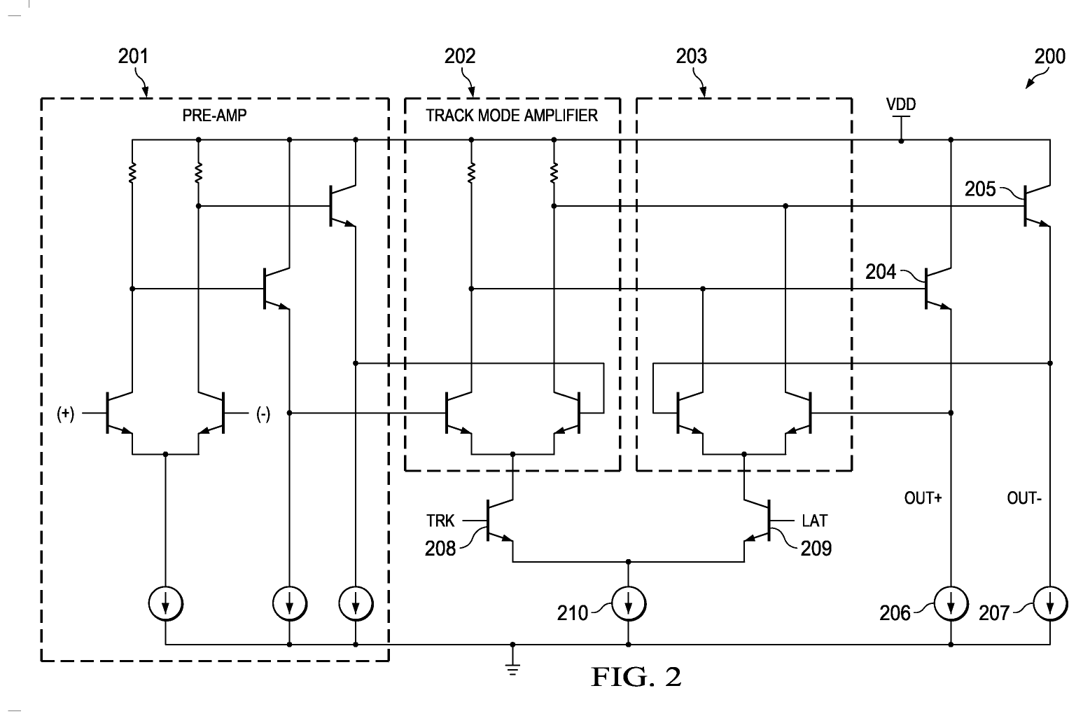

The embodiment shown in FIG. 1 also has a latching time constant that is independent of whatever load is present at the latch outputs. In the typical prior art latch design (e.g., FIG. 2), any load at OUT+/OUT− is contained within the latch positive feedback loop. Thus, the performance of the latch has a dependency on the output loading. This prevents optimization of the latch design without knowing a priori what the load will be.

The embodiment shown in FIG. 1 is also significantly faster than the typical prior art latch design. For a latch, a good figure of merit (FOM) is the latch time constant. This dictates how fast a latch can resolve small signals at its inputs when it enters the LATCH phase. This directly impacts the metastability of the latch, which results in a bit error rate of the latch for a given operating frequency. The embodiment shown in FIG. 1 minimizes the latching time constant for a given process technology operating at a specified power consumption. In addition to the reduction in the number of resistors and transistors connected to and loading the cross-coupled latch, an typical prior art latch also has significant amounts of wiring used to connect the latch. These add parasitic capacitance that negatively impacts the latch time constant. To approach the speeds of the proposed solution, the power consumption of a typical latch will be much higher than the proposed structure.

Minimizing the latch time constant yields several benefits. In a high speed analog to digital converter, for instance, where the latch is used to discriminate between an input voltage and a reference voltage, the time constant impacts how quickly the latch can be clocked without encountering a metastable event. Metastability directly impacts the bit error rate. Lower time constants equal lower bit error rates.

Likewise, if the latch is not required to run at the limits of the given process technology, power can be reduced below that of the standard latch cell for the same performance.

The embodiment shown in FIG. 1 represents application of the inventive principles to a bipolar latch circuit. The inventive principles may also be applied to a complementary metal oxide semiconductor (CMOS) latch circuit, as well.

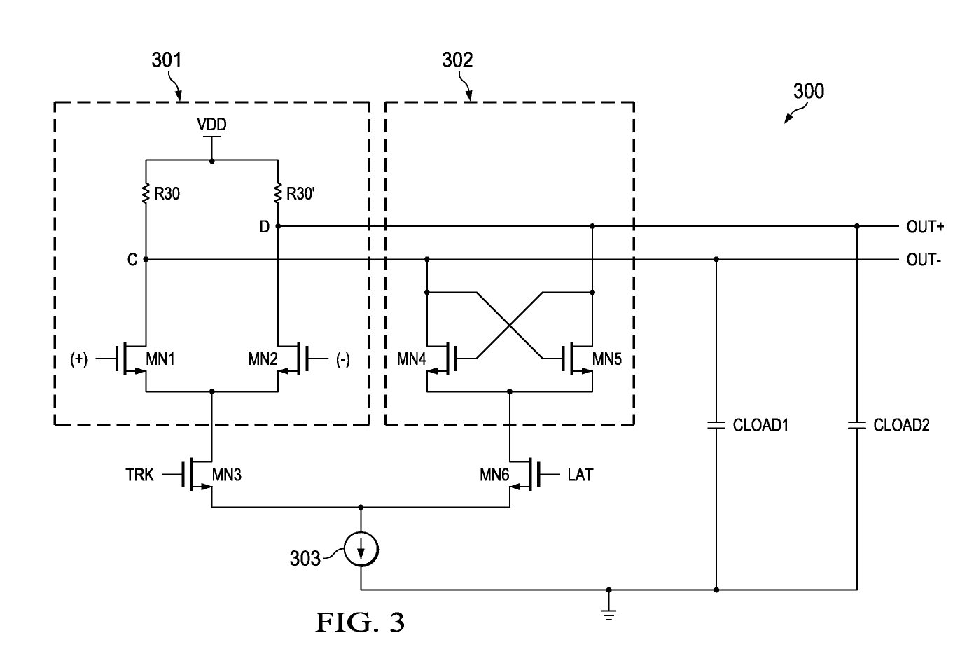

FIG. 3 shows an exemplary prior art CMOS latch circuit. A track-mode amplifier 301 comprises a pair of n-channel metal oxide semiconductor (NMOS) transistors MN1 and MN2, having their sources connected together and having their gates configured to receive the (+) and (−) inputs of the circuit, respectively. Their drains are connected to a power supply at voltage VDD through respective resistors R30 and R30′. The common connection nodes between resistor R30 and transistor MN1 and between resistor R30′ and transistor MN2, nodes C and D, respectively, form the output nodes of the circuit OUT− and OUT+, respectively. A cross-coupled latch 302 comprises NMOS transistors MN4 and MN5 having their sources connected together and each having its gate connected to the other's drain, the drain of transistor MN4 also being connected to node C and the drain of transistor MN5 also being connected to node D. An NMOS transistor MN3 has its drain connected to the common connection node of transistors MN1 and MN2, its gate connected to receive a TRACK signal TRK and its source connected to a current sink 303 connected to ground. An NMOS transistor MN6 has its drain connected to the common connection node of transistors MN4 and MN5, its gate connected to receive a LATCH signal LAT and its source connected to current sink 303 connected to ground. Capacitors Cload1 and Cload2 represent the capacitive load at outputs OUT− and OUT+, respectively.

The CMOS circuit 300 of FIG. 3 suffers similar limitations to circuit 200 of FIG. 2.

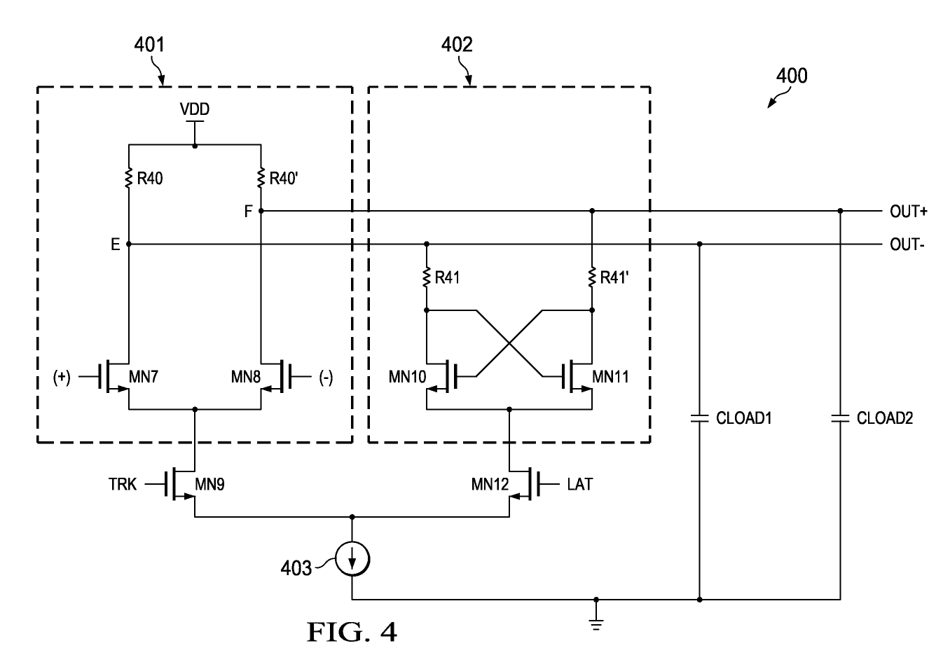

FIG. 4 is a circuit diagram showing a further preferred embodiment of the present invention, representing an improvement to the prior art latched comparator 300 of FIG. 3. The improved latched comparator 400 includes a track-mode amplifier 401 comprising a pair of n-channel metal oxide semiconductor (NMOS) transistors MN7 and MN8, having their sources connected together and having their gates configured to receive the (+) and (−) inputs of the circuit, respectively. Their drains are connected to a power supply at voltage VDD through respective resistors R40 and R40′. The common connection nodes between resistor R40 and transistor MN7 and between resistor R40′ and transistor MN8, nodes E and F, respectively, form the output nodes of the circuit OUT− and OUT+, respectively. A cross-coupled latch 402 comprises NMOS transistors MN10 and MN11 having their sources connected together and each having its gate connected to the other's drain, the drain of transistor MN10 also being connected to node E through a resistor R41 and the drain of transistor MN11 also being connected to node F through a resistor R41′. An NMOS transistor MN9 has its drain connected to the common connection node of transistors MN7 and MN8, its gate connected to receive a TRACK signal TRK and its source connected to a current sink 401 connected to ground. An NMOS transistor MN12 has its drain connected to the common connection node of transistors MN10 and MN11, its gate connected to receive a LATCH signal LAT and its source connected to current sink 401 connected to ground. Capacitors Cload1 and Cload2 represent the capacitive load at outputs OUT− and OUT+, respectively.

Note that similar to the circuit 100, the load resistances of the latch 402 are partially shared and partially split, thus providing reduced load dependency of latch performance compared to circuit 300 of FIG. 3. Further, the cross-coupled latch 402 is isolated from the remainder of the circuit, further reducing load dependency of latch performance, compared to circuit 300.

Although the present invention and its advantages have been described in detail, it should be understood that various changes, substitutions and alterations can be made herein, as well as other embodiments, without departing from the spirit and scope of the invention as defined by the appended claims.

What is claimed is:

1. A latched comparator, comprising:
a pre-amplifier, comprising
a first bipolar transistor and a second bipolar transistor having their emitters connected together, a base of the first bipolar transistor connected to receive a first input, a base of the second bipolar transistor connected to receive a second input,
a first resistor connected between a collector of the first bipolar transistor and a supply port of a power supply,
a second resistor connected between a collector of the second bipolar transistor and the supply port of the power supply, and
a first current sink connected between the common connection node of the first and second bipolar transistor and the power supply ground;
a latch, comprising
a third bipolar transistor and a fourth bipolar transistor having their emitters connected together, a base of each connected to a collector of the other,
a third resistor connected between a collector of the third bipolar transistor and the common connection node of the first transistor and the first resistor, and
a fourth resistor connected between a collector of the fourth bipolar transistor and the common connection node of the second transistor and the second resistor; and
a latch and track select circuit, comprising
a fifth bipolar transistor having an emitter connected to a second current sink connected to ground, having a base connected to receive a latch signal and having a collector connected to the common connection node of the third and fourth transistors, and
a sixth bipolar transistor having an emitter connected to the second current sink connected to ground, having a base connected to receive a track signal and having a collector connected to the supply port of the power supply.

2. The latched comparator of claim 1, further comprising:
a seventh bipolar transistor having a collector connected to the supply port of the power supply, having a base connected to the common connection node of the first transistor and the first resistor and having an emitter connected to a third current sink connected to ground; and
an eighth bipolar transistor having a collector connected to the supply port of the power supply, having a base connected to the common connection node of the second transistor and the second resistor and having an emitter connected to the third current sink connected to ground.

3. A latched comparator, comprising:
a track mode circuit, comprising
a first MOS transistor and a second MOS transistor having their sources connected together, a gate of the first MOS transistor connected to receive a first input, a gate of the second MOS transistor connected to receive a second input,
a first resistor connected between a drain of the first MOS transistor and a supply port of a power supply, and
a second resistor connected between a drain of the second MOS transistor and the supply port of the power supply,
a latch, comprising
a third MOS transistor and a fourth MOS transistor having their sources connected together, a gate of each connected to a drain of the other,
a third resistor connected between a drain of the third MOS transistor and the common connection node of the first transistor and the first resistor, and
a fourth resistor connected between a drain of the fourth MOS transistor and the common connection node of the second transistor and the second resistor; and
a latch and track select circuit, comprising
a fifth MOS transistor having a source connected to a current sink connected to ground, having a gate connected to receive a track signal and having a drain connected to the common connection node of the first and second transistors, and
a sixth MOS transistor having a source connected to the current sink connected to ground, having a gate connected to receive a latch signal and having a drain connected to the common connection node of the third and fourth transistors.
